(19) United States
(12) Patent Application Publication
(10) Pub. No.: US 2011/0294262 A1
(43) Pub. Date: Dec. 1, 2011

(54) SEMICONDUCTOR PACKAGE PROCESS WITH IMPROVED DIE ATTACH METHOD FOR ULTRATHIN CHIPS

(76) Inventors: Ping Huang, Shanghai (CN); Ruisheng Wu, Shanghai (CN); Yi Chen, Shanghai (CN); Lei Duan, Shanghai (CN); Wei Chen, Shanghai (CN); Lihua Bao, Shanghai (CN)

(21) Appl. No.: 12/790,801

(22) Filed: May 29, 2010

(51) Int. Cl. H01L 21/50

(52) U.S. Cl. 438/113; 257/E21.499

(57) ABSTRACT

A semiconductor packaging process with improved die attach method for ultrathin chips package comprises the steps of providing a semiconductor wafer having a wafer frontside and a wafer backside with a plurality of integrated circuit chips (IC chips) formed on the wafer frontside; adhering a supporting substrate onto the wafer frontside through a bonding layer to form a wafer combo; grinding the wafer backside with the supporting substrate and the wafer bonded together; dicing the wafer combo into a plurality of die combos each comprising a substrate piece stacked on top of an IC chip bonded by a bonding layer piece; attaching a die combo onto a die pad of a lead frame with a bottom of the IC chip connected to the lead frame thereof; and removing the substrate piece with the bonding layer piece from the top surface of the IC chip.

### Technical Field

This invention relates to a manufacturing method of semiconductor package. Specifically the invention relates to a semiconductor packaging process with improved die attach method suitable for ultrathin chips package.

### BACKGROUND TECHNOLOGY

In a trend to develop miniature semiconductor chip packages, it is desirable to minimize the thickness of semiconductor wafers to achieve ultrathin chips. This is especially true for vertical semiconductor devices such as vertical power semiconductor devices in that a thick substrate comes with higher substrate resistance therefore increases the overall conduction loss of the device. However, during the package and manufacture process of semiconductor chips, a silicon wafer requires substantial thickness to provide sufficient mechanical strength to avoid wafer or chip breakage during the manufacture process, which could greatly impact the yield in wafer backside processing and in die attach process when grinding the wafer to 100 micron and below.

During die attach process of vertical semiconductor device chip, the semiconductor chips are attached onto a lead frame or a wiring substrate through conductive epoxy; as the epoxy has a very small contact angle with silicon and at the same time due to the migration effect of silver filler, in the traditional packaging process, the conductive epoxy is easy to adhere to the silicon base of the semiconductor chips and climb to the top surface of the semiconductor chip causing short circuit of the integrated circuit, and damaging the electrical performance of the semiconductor chips.

Further, in case the chip is thin, a small movement of the chip during assembly process will cause the conductive epoxy overflow onto the surfaces of the semiconductor chips thereby causing difficulty in the subsequent wire bonding process and resulting in non-stick or incomplete bond . . . In the subsequent molding process, incomplete bond will cause ball lift of the bond wire from the bond pad rendering the device inoperable.

Efforts have been focusing on improving the process to provide ultra thin wafers. For example, in the patent application number US2006/0035443A1 Hsu, et al. disclose a method for partially joins an integrated circuit wafer to a supporting wafer at a limited number of joining points then chemically-mechanically polished to reduce the thickness of the integrated circuit wafer. Next the method cuts through the integrated circuit wafer and the supporting wafer to form chip sections. During this cutting process, the integrated circuit wafer separates from the supporting wafer in chip sections where the integrated circuit wafer is not joined to the supporting wafer by the joining points. The disclosure helps to provide ultra thin chips but does not provide improvement in die attach. Therefore it is desirable to develop a process that is capable of providing ultra thin wafer and improve the ultra thin chip die attach process.

### SUMMARY OF INVENTION

In order to resolve the technique problems, this invention provides a wafer thinning and die attach method for ultrathin wafers with the advantages of low cost, simple production and manufacture process; moreover, the method effectively improves the product yield and improves the performance of circuit on the chip.

This invention provides a die attach method used on ultrathin wafer technique, which comprises the following steps:

Providing a semiconductor wafer having a wafer frontside and a wafer backside, wherein a plurality of integrated circuit chips (IC chips) formed on the wafer frontside;

Providing a bonding layer;

Providing a supporting substrate and adhering the supporting substrate onto the wafer frontside through the bonding layer;

Grinding the wafer backside with the supporting substrate and the wafer bonded together;

Cutting the wafer and the supporting substrate into the plurality of chip combos each having a substrate piece bonded to a top surface of an IC chip;

Attaching a bottom of the IC chip on a lead frame thereof; and

Removing the substrate piece from the top surface of the IC chip.

In one embodiment the method further comprises a step of wafer backside process after grinding the wafer backside, wherein the wafer backside process includes backside etching, backside evaporating, backside implantation as well as backside laser annealing.

In one embodiment the bonding layer is a thermal release double-side adhesive tape with one side of the thermal release double-side adhesive tape comprises a pressure-sensitive adhesive bonding layer and the other surface comprises a thermal release adhesive bonding layer; wherein the pressure-sensitive adhesive bonding layer being adhered onto the supporting substrate and the thermal release adhesive bonding layer adhered onto the wafer frontside. In anther embodiment the bonding layer is a UV release double-side adhesive tape with one side of the UV release double-side adhesive tape comprises a UV self-releasing adhesive layer and the other side comprises a UV releasing assisted adhesive layer; wherein the UV releasing assisted adhesive layer being adhered onto the supporting substrate and the UV self-releasing adhesive layer adhered onto the wafer frontside.

In one embodiment the step of removing the substrate piece from the top surface of the IC chip further comprising a step of heating the bonding layer to release the bonding layer from the IC chip. In another embodiment the step of removing the substrate piece from the top surface of the IC chip further comprising a step of UV radiating the bonding layer to release the bonding layer from the IC chip.

In another embodiment the step of grinding the wafer backside further grinds the wafer backside to a wafer thickness of less than or equal to 100 micron.

### BRIEF DESCRIPTION OF FIGURES

FIG. 1 is the structure of a single-side adhesive tape.

FIG. 2 is the structure of a double-side thermal release adhesive tape.

FIG. 3 is the structure of a double-side UV self-releasing adhesive tape.

FIG. 4 is the schematic cross section of sticking the supporting substrate on the wafer frontside through the bonding layer therefore providing a wafer combo.

FIG. 5 is the schematic cross section of the grinded wafer combo provided with the supporting substrate.

FIG. 6 is the schematic cross section of sticking the wafer combo onto the cutting film.

FIG. 7 is the schematic cross section of cutting the wafer combo into a plurality of die combo.

FIG. 8 is the plan view of the wafer combo divided into the plurality of die combos.

FIG. 9 is the schematic cross section of sticking the die combo onto the lead frame.

FIG. 10 is the schematic cross section of the semiconductor chips attached on the lead frame after peeling off the substrate pieces and the bonding pieces from the top of semiconductor chips.

FIG. 11 is a flow chart of a semiconductor packaging process with an improved die attach method suitable for ultrathin semiconductor chips packages.

### DETAILED DESCRIPTION OF THE INVENTION

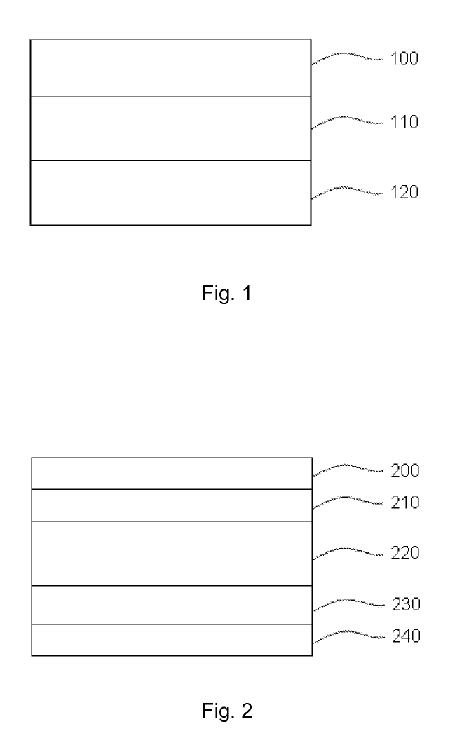

As shown in FIG. 1, a single-side adhesive tape comprises a release liner 100, a thermal release adhesive bonding layer 110, and a polyester backing layer 120; the release liner 100 is used for protecting the thermal release adhesive bonding layer 110; when in use, the release liner 100 is torn off and the thermal release adhesive bonding layer 110 plays the role of bonding.

As shown in FIG. 2, compared with the single-side adhesive tape, a double-side thermal release adhesive tape such as the REVALPHA brand provided by Nitto Denko Corporation of Japan, comprises a first release liner 200 and a second release liner 240, a thermal release adhesive bonding layer 210, a polyester backing layer 220 and a pressure sensitive adhesive bonding layer 230. The first release liner 200 and the second release liner 240 are respectively used to protect the thermal release adhesive bonding layer 210 and the pressure sensitive adhesive bonding layer 230 respectively; whereas the thermal release adhesive bonding layer 210 and the pressure sensitive adhesive bonding layer 230 play the role of bonding; and the bonding force of the thermal release adhesive bonding layer 210 can be adjusted through temperature.

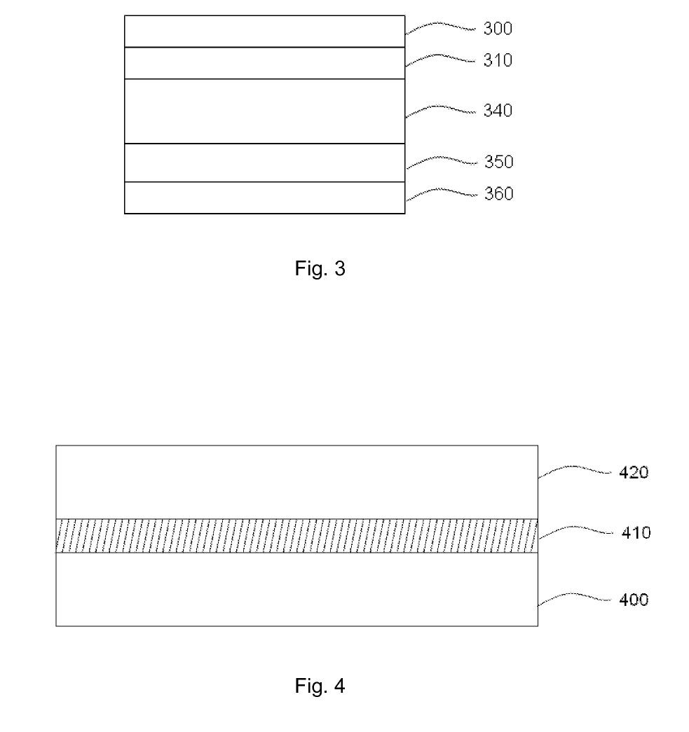

As shown in FIG. 3, a double-side UV self-releasing adhesive tape such as the standard Selfa BG supplied by Sekisui Chemical Co., Ltd of Japan, comprises a first release liner 300, a second release liner 360, an UV self-releasing adhesive layer 310, a base film 340 and an UV releasing assist adhesive layer 350; wherein the UV self-releasing adhesive layer 310 and the UV releasing assist adhesive layer 350 play the role of bonding. When the UV light irradiation intensity is within a certain range, the UV self-releasing adhesive layer 310 completely releases through gas emission and separates from the bonding surface.

As shown in FIG. 4, wafer 400 comprises a wafer frontside and a wafer backside; integrated circuit elements are formed on the wafer frontside and a supporting substrate 420 is attached on the frontside of the wafer 400 through a bonding layer 410 therefore forming a wafer combo. In one preferable embodiment, the bonding layer 410 is the double-side thermal release adhesive tape as shown in FIG. 2; the pressure sensitive adhesive bonding layer of the bonding layer 410 is adhered onto the supporting substrate 420 and the thermal release adhesive bonding layer of the bonding layer 410 is attached on the frontside of the wafer 400. In another embodiment, the bonding layer 410 is the double-side UV releasing adhesive tape; the UV releasing assist adhesive layer of the bonding layer 410 is adhered onto the supporting substrate 420; and the UV self-releasing adhesive layer of the bonding layer 410 is adhered onto the frontside of the wafer 400.

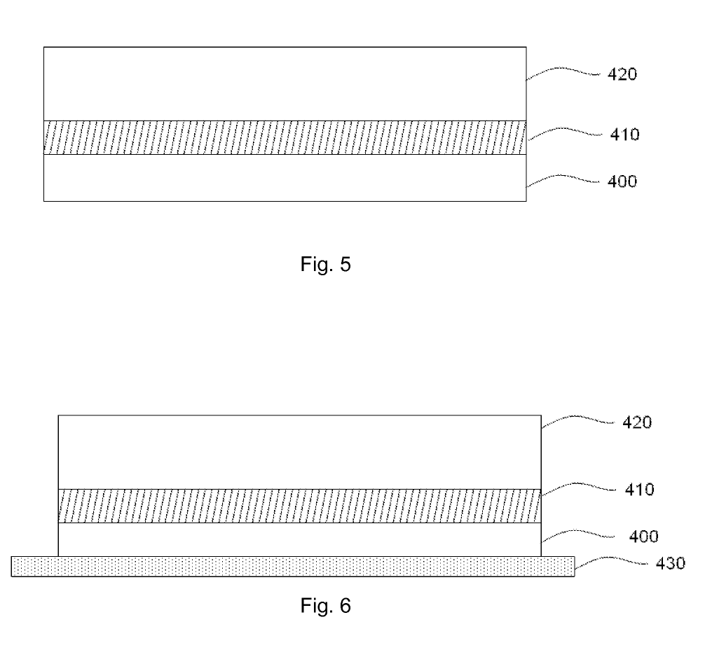

As shown in FIG. 5, a way of cutting or grinding can be adopted to implement wafer thinning on the backside of the wafer 400 in the FIG. 4. As the supporting substrate 420 on the wafer 400 enhances the mechanical strength of the wafer 400, the thickness of wafer 400 can be reduced to 100 micron or below. For vertical power semiconductor devices, after the wafer 400 is grinded, wafer backside processing like etching, evaporation, ion implantation and laser annealing may be implemented on the backside of the wafer 400 so as to form the backside electrode of the semiconductor chip.

As shown in the FIG. 6, the backside of the wafer 400 obtained through backside grinding and backside processing is attached onto a cutting film 430 with the supporting substrate 420 on the top surface of the wafer.

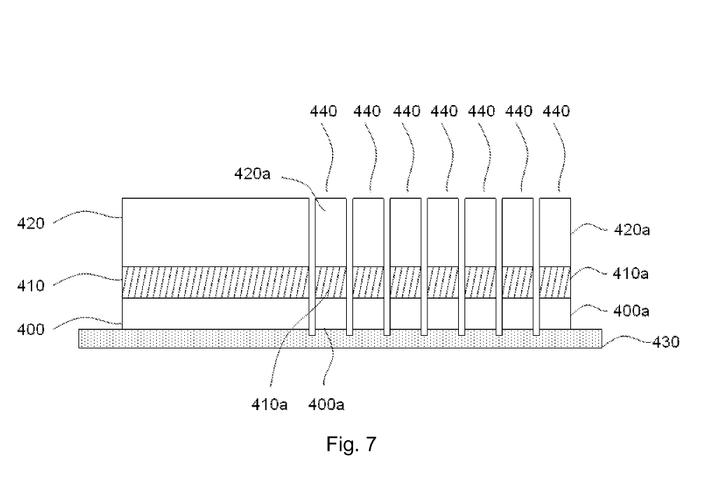

As shown in the FIG. 7, the wafer 400 provided with the supporting substrate 420 attached to the cutting film 430 is cut according to the chip size into a plurality of semiconductor chips; the supporting substrate 420, the bonding layer 410 and the wafer 400 are cut through at the same time to yield a plurality of chip combos 440 each combined with a substrate piece 420a of the supporting substrate, a bonding layer piece 410a and a semiconductor chip 400a; the bonding layer piece 410a maintain the bonding characteristics of the bonding layer therefore bonds the substrate piece 420a of the supporting substrate to the semiconductor chip 400a. Meanwhile, the cutting film 430 is cut only partially through a small portion on the top therefore the entire cutting film remains intact. As a cutting device needs to see through the supporting substrate 420 to identify the boundaries of each chip optically, the supporting substrate 420 is preferably made of transparent material so that an optical device can read the size of the single die of the wafer 400a; therefore, glass or quartz material with good transparency to the optical device is preferably selected as the supporting substrate 420.

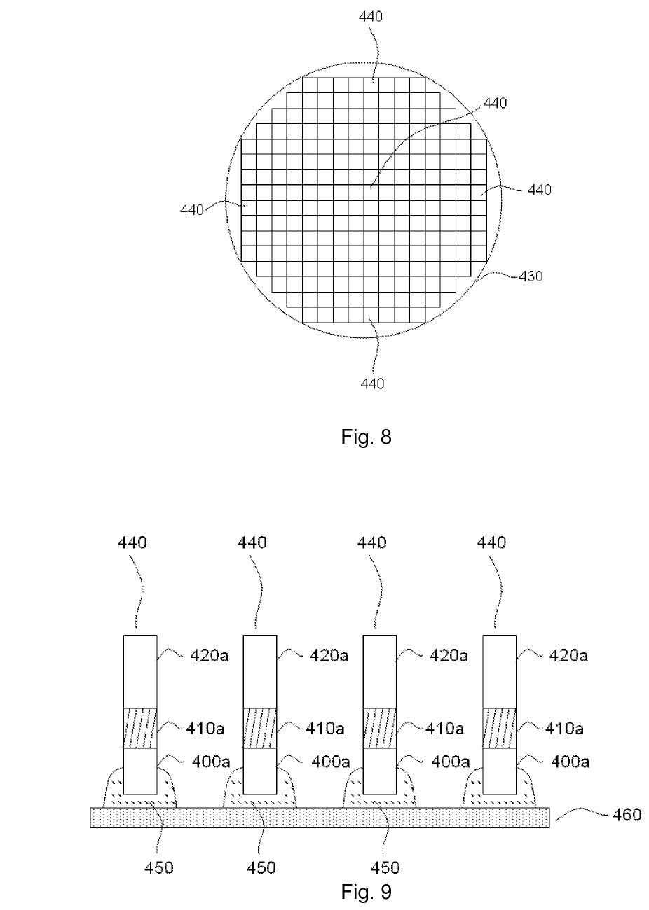

As shown in FIG. 8, the whole wafer combo is cut into a plurality of chip combos 440 on the cutting film 430.

As shown in FIG. 9, a lead frame 460 is provided with a die pad area. An adhesive is dispensed on the die pad of the lead frame 460. In the case the semiconductor chip to be packaged is a vertical semiconductor device such as a vertical power MOSFET, conductive adhesive is dispensed on the die pads of lead frame to form a plurality of conductive epoxy areas 450 and a plurality of chip combos 440 are die attached onto the conductive epoxy areas 450 respectively with the bottom surface of each semiconductor chip 400a connected to the die pad through the bonding effect of the conductive epoxy in the conductive epoxy areas 450. The process of die attach can attach a plurality of the semiconductor chips 400a onto one lead frame die pad with a substrate piece attached on top of each chip; alternatively a single chip combo can be stuck on the lead frame 460 depending on the actual packaging requirement.

Compared to the known practice of sticking the semiconductor chips 400a on the lead frame without the supporting substrate, when the thickness of the semiconductor chip 400a is 100 micron or below, the fragility of semiconductor chip 400a alone could cause technical difficulty during the processes of cutting and die attach. The substrate piece 420a of the supporting substrate therefore enhances the mechanical strength of the semiconductor chip 400a so as to avoid the semiconductor chip 400a from cracking during the die attach process.

Further as each of the chip combo 440 comprises the substrate piece 420a of the supporting substrate bonded by the bonding layer piece 410a of the bonding layer to the top surface of the semiconductor chip 400a, when the backside of the semiconductor chip 400a is affixed onto the lead frame 460 through the conductive epoxy areas 450, the substrate piece 420a of the supporting substrate and the bonding piece 410a of the bonding layer cover the integrated circuit disposed at the frontside of the semiconductor chip 400a so as to avoid the conductive epoxy from contacting the integrated circuit area of the semiconductor chip 400a caused by over flow of conductive epoxy due to over supply epoxy or lateral movement of the semiconductor chip 400a in the conductive epoxy areas.

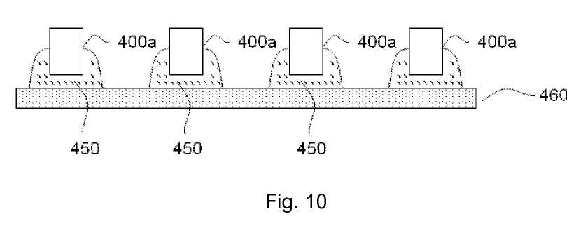

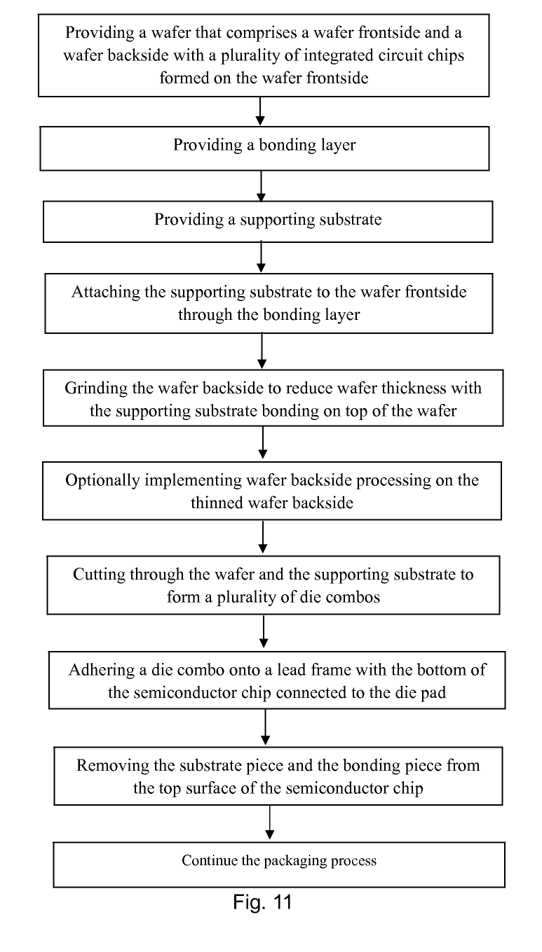

The substrate piece 420a of the supporting substrate and the bonding piece 410a of the bonding layer can be moved from each chip combo 440 after the conductive epoxy areas 450 are cured so as to finish die attach process to obtain an assembly of semiconductor chips 400a attached to die pad of lead frame 460 as shown in FIG. 10. In one preferable embodiment, the bonding piece 410a of the bonding layer is the double-side thermal release adhesive tape as shown in FIG. 2. With the thermal release adhesive bonding layer attaching onto the top surface of the semiconductor chip loses stickiness under high temperature through heating the double-side thermal release adhesive tape, the bonding piece 410a of the bonding layer and the substrate piece 420a of the supporting substrate together can be peeled off from the top surface of each semiconductor chip 400a. The adhesive releasing temperature ranges from 90 degree C. to above 150 degree C. In another preferable embodiment, the bonding piece 410a of the bonding layer 410 is the double-side UV self-releasing adhesive tape as shown in FIG. 3. By implementing UV light irradiation on the double-side UV self-releasing adhesive tape the UV self-releasing adhesive tape loses the stickiness thereby the bonding piece 410a of the bonding layer and the substrate piece 420a of the supporting substrate together can be peeled off from the top surface of each semiconductor chip 400a.

The assembly shown in FIG. 10 may continue with wire bonding and encapsulation molding to complete the packaging process. In summary, as shown in the FIG. 11, the packaging process with improved die attach method suitable for packaging ultrathin semiconductor chips comprises the following steps:

Providing a wafer that comprises a wafer frontside and a wafer backside with a plurality of integrated circuit chips formed on the wafer frontside; providing a bonding layer; providing a supporting substrate and attaching the supporting substrate to the wafer frontside through the bonding layer; grinding the wafer backside to reduce wafer thickness with the supporting substrate bonding on top of the wafer; optionally implementing wafer backside processing on the thinned wafer backside so as to form a device backside electrode; adhering the bottom of the wafer onto a cutting film with the supporting substrate bonded on top of the wafer and cutting through the wafer and the supporting substrate so as to form a plurality of die combo each comprising a semiconductor chip with a substrate piece of the supporting substrate sticking on top of the semiconductor chip through a bonding piece of the bonding layer; providing a lead frame with a die pad and adhering a die combo onto the lead frame with the bottomed of the semiconductor chip connected to the die pad; removing the substrate piece and the bonding piece from the top surface of the semiconductor chip; wire bonding the chip to the lead frame and encapsulating the chip with molding compound.

Although the foregoing embodiments have been described in some detail for purposes of clarity of understanding, the invention is not limited to the details provided. There are many alternative ways of implementing the invention. The disclosed embodiments are illustrative and not restrictive.

1. A method for packaging semiconductor chips comprises the following steps:
providing a semiconductor wafer having a wafer frontside and a wafer backside, wherein a plurality of integrated circuit chips (IC chips) formed on the wafer frontside;
providing a bonding layer;
providing a supporting substrate and adhering the supporting substrate onto the wafer frontside through the bonding layer;
thinning the wafer backside with the supporting substrate and the wafer bonded together;
dicing the wafer and the supporting substrate into the plurality of chip combos each having a substrate piece bonded to a top surface of the IC chip;
attaching a bottom of an IC chip on a lead frame thereof; and
removing the substrate piece from the top surface of the IC chip.

2. The method of claim 1 further comprises a step of wafer backside process after thinning the wafer backside.

3. The method of claim 2 wherein the backside process includes backside etching, backside evaporating, backside implantation as well as backside laser annealing.

4. The method of claim 1 wherein the supporting substrate is a glass or a quartz.

5. The method of claim 1 wherein the bonding layer is a thermal release double-side adhesive tape.

6. The method of claim 5 wherein one side of the thermal release double-side adhesive tape is a pressure-sensitive adhesive bonding layer and the other side is a thermal release adhesive bonding layer; wherein the pressure-sensitive adhesive bonding layer being adhered onto the supporting substrate and the thermal release adhesive bonding layer being adhered onto the wafer frontside.

7. The method of claim 6 wherein the step of removing the substrate piece from the top surface of the IC chip further comprising a step of heating the bonding layer to release the bonding layer from the IC chip.

8. The method of claim 1 wherein the bonding layer is a UV release double-side adhesive tape.

9. The method of claim 8 wherein one side of the UV release double-side adhesive tape is a UV self-releasing adhesive layer and the other side is a UV releasing assisted adhesive layer; wherein the UV releasing assisted adhesive layer being adhered onto the supporting substrate and the UV self-releasing adhesive layer adhered onto the wafer frontside.

10. The method of claim 9 wherein the step of removing the substrate piece from the top surface of the IC chip further comprising a step of UV radiating the bonding layer to release the bonding layer from the IC chip.

11. The method of claim 1 wherein the step of thinning the wafer backside further grinds the wafer backside to a wafer thickness of less than or equal to 100 micron.
